(19) United States
(12) Patent Application Publication
(10) Pub. No.: US 2014/0306172 A1
(43) Pub. Date: Oct. 16, 2014

(54) INTEGRATED CIRCUIT SYSTEM WITH NON-VOLATILE MEMORY AND METHOD OF MANUFACTURE THEREOF

(71) Applicant: SONY CORPORATION, Tokyo (JP)

(72) Inventors: Scott Sills, Boise, ID (US); Muralikrishnan Balakrishnan, Boise, ID (US); Beth Cook, Meridian, ID (US); Durai Vishak Nirmal Ramaswamy, Boise, ID (US); Shuichiro Yasuda, Boise, ID (US)

(73) Assignee: Sony Corporation, Tokyo (JP)

(21) Appl. No.: 13/862,201

(22) Filed: Apr. 12, 2013

(51) Int. Cl. H01L 45/00; H01L 21/28

(52) U.S. Cl. CPC H01L 45/1608; H01L 45/1253; H01L 21/28
USPC 257/4; 438/382

(57) ABSTRACT

An integrated circuit system, and a method of manufacture thereof, including: an integrated circuit die having an address switch; a bottom electrode contact, free of halogen constituents, characteristic of a chemical vapor deposition or an atomic layer deposition, and coupled to the address switch; a transition material layer directly on the bottom electrode contact; and a top electrode contact, directly on the transition material layer, for forming a non-volatile memory array on the integrated circuit die.

### TECHNICAL FIELD

The present invention relates generally to an integrated circuit system, and more particularly to a system for integration of high-density non-volatile memory arrays in integrated circuit applications.

### BACKGROUND ART

Personal electronic devices are growing in versatility and intelligence. The trend for including ever-increasing amounts of memory in these devices has presented challenges to the integrated circuit manufacturing industry that impose conflicting requirements on the integrated circuits. In order to accommodate the increased amount of logic and memory, smaller and smaller geometries are required to contain the functions.

The smaller geometries of crystalline structures used to fabricate the integrated circuits can represent insurmountable challenge to the operation of charge based memory technologies. Memories such as non-volatile flash memory or dynamic random access memory (DRAM) maintains the data content by storing charge within a physical structure in the memory cell. With the thinner crystalline structures associated with smaller geometry technologies, the charge can damage the crystalline structure or leak through the physical structures. Many approaches have been attempted to maintain data integrity in view of the less reliable crystalline structures. Approaches such as wear leveling, variable error correction codes, and extended parity schemes have been used to mask the reliability issues of the smaller geometry crystalline structures.

Other memory technologies not dependent on charge storage are making their way to the main stream manufacturing processes. These technologies include Resistive Random Access Memory (RRAM) and Conductive Bridging Random Access Memory (CBRAM), which can change resistance values when written or erased. While these mechanisms can be utilized on any of the small geometry technologies, they have not been able to be produced in a volume that enables commodity status. The manufacturing reliability and performance has been suspect and research continues for ways to provide consistent yield and performance that can be integrated with popular commodity items like smart phones, digital cameras, global positioning systems, personal audio players, portable gaming devices.

Thus, a need still remains for an integrated circuit system with non-volatile memory. In view of the ever-increasing public demand to deliver more functionality, lower costs, and increased performance, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit system including: providing an integrated circuit die having an address switch; forming a bottom electrode contact, free of halogen constituents, having characteristics of a chemical vapor deposition or an atomic layer deposition process, and coupled to the address switch; depositing a transition material layer directly on the bottom electrode contact; and depositing a top electrode contact directly on the transition material layer for forming a non-volatile memory array on the integrated circuit die.

The present invention provides an integrated circuit mounting system, including: an integrated circuit die having an address switch; a bottom electrode contact, free of halogen constituents, characteristic of a chemical vapor deposition or an atomic layer deposition, and coupled to the address switch; a transition material layer directly on the bottom electrode contact; and a top electrode contact directly on the transition material layer for forming a non-volatile memory array on the integrated circuit die.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a block diagram of an integrated circuit system with non-volatile memory in an embodiment of the present invention.

FIG. 2 is a schematic diagram of the non-volatile memory cell of FIG. 1.

FIG. 3 is an exemplary graph of resistivity versus thickness for depositions of titanium nitride and titanium silicon nitride.

FIG. 4 is an exemplary graph plotting read memory cyclic set and reset endurance exemplifying one of the four versions of the bottom electrode contact of FIG. 3.

FIG. 5 is an exemplary graph plotting memory state retention stability of a memory cell of one of the four versions of the bottom electrode contact of FIG. 3.

FIG. 6 is a partial cross-sectional view a bottom electrode contact in a deposition processing phase of manufacturing.

FIG. 7 is a flow chart of a method of manufacture of an integrated circuit system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

For expository purposes, the term “horizontal” as used herein is defined as a plane parallel to the active surface of the integrated circuit die, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means there is direct contact between elements with no intervening elements.

The term “processing” as used herein includes deposition of material or photoresist, patterning, exposure, development, etching, cleaning, and/or removal of the material or photoresist as required in forming a described structure. The term “back end-of-line processing” means the fabrication of additional functional layers over the passivation layer of an integrated circuit die that can connect exposed contacts. The term “TDMAT” is defined as tetrakis-dimethylamino titanium Ti(N(CH₃)₂)₄ as used in this specification. The molecular formula (CH₃)₅C₅Ti(CH₃)₃ is defined as the chemical named (Trimethyl)pentamethylcyclopentadienyltitanium(IV) as used in this specification.

The term “precursor” as used herein means a first material, deposited or introduced on a site, and can be altered to become a second material through at least one chemical reaction. The term “floating voltage” as used herein means a connected voltage source has been removed or switched off allowing the coupled line to take on the low voltage, typically between 0.3 and 0.7 volts, provided by the bias of the next coupled input.

The term “trace halogens” as used herein means residual traces of compounds including chlorine (Cl), fluorine (Fl), bromine (Br), or iodine (I). The term “not having any trace of halogen” as use herein means complete absence of any molecular trace or evidence of halogen constituents.

Resistive change based memory cells rely on an active electrode to inject/absorb the transport species during set and reset operations, and a counter electrode that is electrochemically inert with respect to the physical switching mechanism(s). The nature of the inert electrode contact with the active cell region is critical to achieving performance specifications. Resistance, geometry, roughness, material work function, and cation affinity can depend on the material deposition method, and the availability of certain methods may be limited by structural constraints associated with the substrate topology.

A bottom electrode contact (BEC) may require depositing the electrode material into a pre-patterned contact hole via or narrow trench and a physical vapor deposition (PVD) is often not able to provide sufficient fill prior to pinch-off and void formation. Chemical vapor deposition (CVD) techniques are required to provide sufficient fill requirements necessary to produce the BEC. Results of the CVD results can depend on chemical precursors used.

For example , chloride residue or bi-products, dependent on the chemical precursors, can degrade performance of the memory cell. It is necessary to control the trace composition of the BEC so that the BEC remains inert. Hence, stable BEC materials are vital for RRAM memory cells and high density RRAM memory arrays performance and reliability.

This invention, described in the figures that follow, provides a CVD/ALD TiN inert electrode based on organometallic Ti precursor, which does not contain any trace halogens, is able to tune final electrode resistivity based on plasma exposure conditions during deposition, and is capable of filling small contact-holes.

It will be apparent that as deposited TDMAT—based TiN is has resistive characteristics that can be tuned to match the TiCl₄-based TiN, by adjusting plasma exposure and power, produces significantly better performance improvements, and exhibits 3-sigma endurance limits beyond 100 k cyc, and superior improvement in LRS retention. It will also be apparent that modification of the TDMAT TiN with the addition of Si can produce memory cells with a more stable read window budget and improved memory endurance.

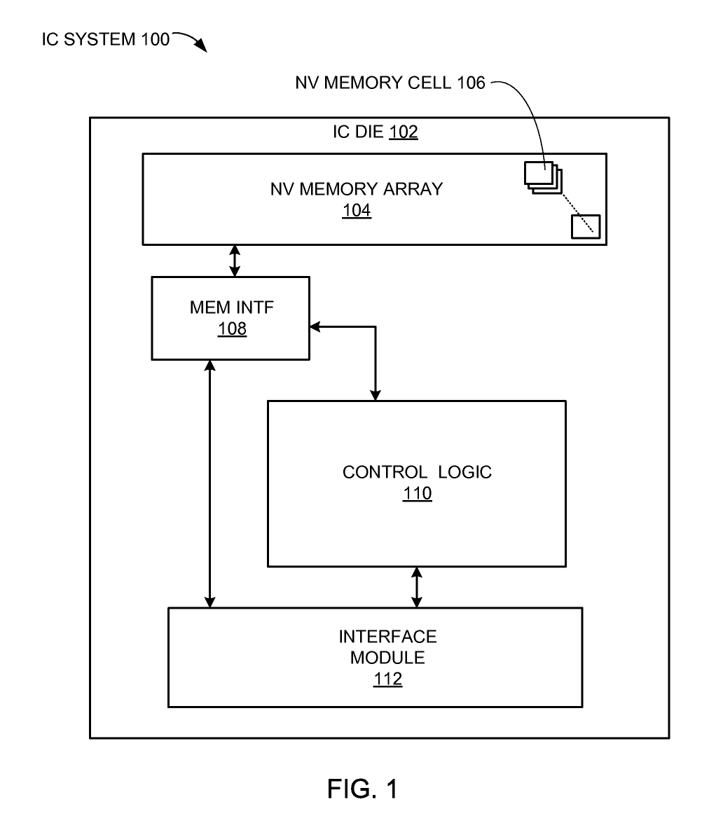

Referring now to FIG. 1, therein is shown a block diagram of an integrated circuit system 100 with non-volatile memory in an embodiment of the present invention. The block diagram of the integrated circuit system 100, also referred to as the IC SYSTEM, depicts an integrated circuit die 102, shown labeled and also referred to as IC DIE, having a non-volatile memory array 104 including at least one non-volatile memory cell 106.

The non-volatile memory cell 106, shown labeled and also referred to as NV MEMORY CELL. The non-volatile memory cell 106 can be a resistive memory cell of the type used in resistive random access memory (RRAM), conductive bridging random access memory (CBRAM), or any memory technology altering cell resistances to store a data condition state, such as a one (1) or a zero (0). The data condition state of the non-volatile memory cell 106 can be referred to as the memory contents or data information, processed or used by a program, a user, or an application.

A memory interface 108 can be coupled to the non-volatile memory array 104. The memory interface 108, shown labeled and also referred to as MEM INTF, includes sense amplifiers, address drivers, voltage sources, data integrity checking logic, and switching logic required to address and effect the state of the non-volatile memory cell 106 within the non-volatile memory array 104, shown labeled and also referred to as NV MEMORY ARRAY.

A control logic 110 can access the memory interface 108 in order to utilize the non-volatile memory array 104. The control logic 110 can include a sequential processor, a bit-slice processor, a micro-processor, or a combinational logic control array (not shown). The control logic 110 can be coupled to the non-volatile memory array 104 to perform operations on the non-volatile memory array 104 in order to write, read, or erase the non-volatile memory cell 106. The control logic 110 can also provide error correction algorithms in order to maintain the integrity of user data stored in the non-volatile memory array 104.

The control logic 110 can be coupled to an interface module 112 for communication beyond the boundaries of the integrated circuit die 102. The interface module 112 can also be coupled to the memory interface 108 for efficient transfer of multiple blocks of the user data to or from the non-volatile memory array 104 without direct intervention of the control logic 110.

It is understood that the description of the integrated circuit system 100 is clarify the invention and is not intended to limit the scope or architecture of the integrated circuit die 102. It is further understood that additional functions can be implemented in the integrated circuit die 102 that can operate in concert or replace some of the previously defined blocks.

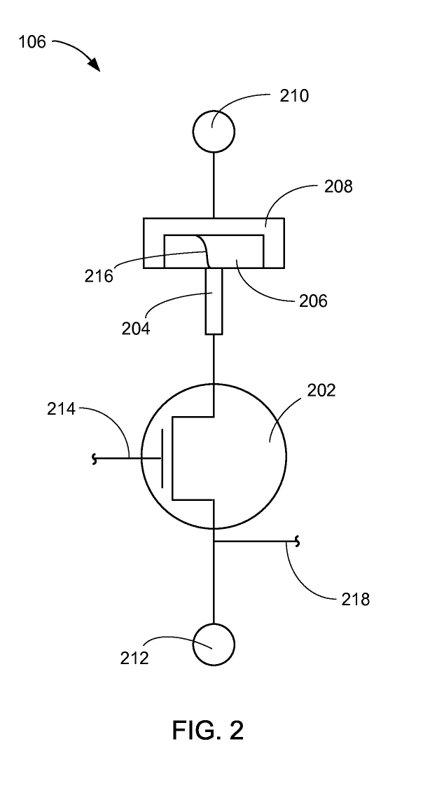

Referring now to FIG. 2, therein is shown a schematic diagram of the non-volatile memory cell 106 of FIG. 1. The schematic diagram of the non-volatile memory cell 106 depicts an address switch 202, such as a Field Effect Transistor (FET) or a multiplexer coupled to a bottom electrode contact 204, also known as inert electrode contact or inert contact. In other embodiments, not illustrated, for example, a crosspoint memory array architecture, the “address switch” may comprise a “non-ohmic device”, such as a rectifying diode or a symmetric non-linear device.

The switching mechanism of ReRAM and CBRAM includes ion movement under an applied electric field. The bottom electrode contact 204 is electrochemically and thermally inert with respect to the atoms involved in the physical switching mechanism of the non-volatile memory cell 106 to prevent unintended movement of ions not related to resistive switching. The physical switching mechanism can include changes in electrical resistance due to reversible atomic displacements or changes of charge based memories.

The bottom electrode contact 204, shown labeled and also referred to as BEC or BE CONTACT, can be formed as a contact via in the integrated circuit die 102 of FIG. 1 having a diameter of less than one hundred ηm. A preferred embodiment of the bottom electrode contact 204 can have a diameter that measures less than 30 ηm. The small diameter of the bottom electrode contact 204 can allow a very dense pattern of the non-volatile memory cell 106 to be formed in the non-volatile memory array 104 of FIG. 1.

A transition material layer 206, shown labeled and also referred to as TRANSITION LAYER, such as a dielectric or metal oxide material that can act as an ion conducting solid-electrolyte, can be formed directly on the bottom electrode contact 204. The transition material layer 206 can be formed of one or more layers of material used to provide the data condition state of the non-volatile memory cell 106. The data condition state can be indicated by a change in resistance of the transition material layer 206 as a result of applied energy, such as voltage or current, to the transition material layer 206.

In a neutral state, the transition material layer 206 represents an insulating layer relative to the bottom electrode contact 204. The transition material layer 206 can be formed within the bounds of the integrated circuit manufacturing process or it can be applied as a back-end of line (BEOL) process after the integrated circuit die 102 of FIG. 1 has completed fabrication and testing. The thickness and pattern, of the transition material layer 206, can be formed by a photolithography and etch process known in the semiconductor industry.

A top electrode contact 208, such as an active ion interchange layer, can be deposited on a top surface of the transition material layer 206 and over the integrated circuit die 102. The transition material layer 206 can be formed having an active ion layer and an inert top electrode (not shown) divided from one another. The top electrode contact 208, shown labeled and also referred to as TE CONTACT, can contribute to or absorb ions from the transition material layer 206. The top electrode contact 208 can be coupled to a first voltage source 210, shown labeled and also referred to as FIRST VS, which can be used to motivate the interchange of ions between the transition material layer 206 and the top electrode contact 208.

A second voltage source 212, shown labeled and also referred to as SECOND VS, can be coupled to the address switch 202. The address switch 202 can be activated by a word line 214, which allows the address switch 202 to apply the voltage from the second voltage source 212 to the bottom electrode contact 204.

The potential difference between the first voltage source 210 and the second voltage source 212 can determine the operation performed by the non-volatile memory cell 106. The operation can be a write, storing a data “1” by transferring sufficient ions between the transition material layer 206 and the top electrode contact 208 to form a conductive bridge 216. The conductive bridge 216 can form a low resistance connection between the bottom electrode contact 204 and the top electrode contact 208. The conductive bridge 216 can remain in place whether or not power is applied to the system, thus making the conductive bridge 216 non-volatile. The operation can be an erase, which reverses the polarity of the voltage applied to form the conductive bridge 216 in order to drive the ions back into their neutral position. The reset operation restores the condition of the transition material layer 206 and the top electrode contact 208 and removes the conductive bridge 216 providing a high resistance between the bottom electrode contact 204 and the top electrode contact 208.

The operation can be a read of the state of the non-volatile memory cell 106. In the read, the first voltage source 210 can provide a sense voltage and the second voltage source 212 can be switched off to present a floating voltage. If the non-volatile memory cell 106 contains the data “1”, indicated by the presence of the conductive bridge 216, the sense voltage will be gated through the address switch 202 and presented on a bit line 218. If the non-volatile memory cell 106 contains a data “0”, indicated by the absence of the conductive bridge 216, the bit line 218 will not be driven by the sense voltage and will reflect the floating voltage from the next coupled input (not shown).

The bottom electrode contact 204 is formed as an inert contact containing or having titanium nitride and without any trace of halogen constituents as a result of depositing a precursor of an organometallic compound, such as either TDMAT or (CH₃)₅C₅Ti(CH₃)₃, show or exhibit characteristics of a chemical vapor deposition (CVD), atomic layer deposition (ALD), or a combination of both CVD and ALD deposition process.

A deposition temperature determines or decides amounts of unreacted residue such as halogens and Carbon. The amount of unreacted residue and or the deposition temperature determine a crystallography of materials and resistivity of materials.

The characteristics of the CVD/ALD deposition used to form the bottom electrode contact 204 can include a crystalline structure of one or more individual layer with each individual having specified atomic constituents, such as titanium nitride, titanium silicon nitride, tungsten, or a combination thereof, aligned and intersecting a common plane within the layer visible thru cross-sectional electronic renditions, such as in electron microscopy, x-ray diffraction, energy dispersive spectrometry (EDS) imaging, or equivalent imaging devices used for detecting and determining physical attributes of a crystalline structure.

It is understood that the top electrode contact 208 is shown on the top and vertical sides of the transition material layer 206 but can be limited to only a portion of the surface of the transition material layer 206 opposite the bottom electrode contact 204 without changing the described operation. It is also understood that the formation of the conductive bridge 216 can be caused by the injection of ions into the transition material layer 206, or the attraction of ions out of the transition material layer 206 depending on the type of material used for the transition material layer 206. It is further understood that while only the conductive bridge 216 is shown, there can be a plurality or multiples of the conductive bridge 216 formed in the transition material layer 206.

It has been discovered that the bottom electrode contact 204, of the non-volatile memory cell 106 in direct contact to the transition material layer 206, can be formed in the integrated circuit die 102 to be an inert contact containing or having titanium nitride not having any trace of halogen constituents as a result of depositing a precursor of an organometallic compound, such as either TDMAT or (CH₃)₅C₅Ti(CH₃)₃, by chemical vapor deposition (CVD), atomic layer deposition (ALD), or a combination of both CVD and ALD depositions in an opening and exposing the organometallic titanium, thus the inert contact free of halogen constituents provides optimum performance of the non-volatile memory cell 106.

It has been discovered that the bottom electrode contact 204, of the non-volatile memory cell 106 in direct contact to the transition material layer 206, can be formed in the integrated circuit die 102 by chemical vapor deposition (CVD), atomic layer deposition (ALD), or a combination thereof, to be an inert contact containing or having titanium nitride, not having any halogen constituents, and having a fine tuned resistance based on plasma exposure conditions applied during the deposition, thus the inert contact having fine tuned resistance characteristics provide optimum performance of the non-volatile memory cell 106.

It has been discovered that the titanium nitride (TiN) of the bottom electrode contact 204, formed from the organometallic compound using either TDMAT or (CH₃)₅C₅Ti(CH₃)₃, formed completely free of trace halogens, having an amorphous structure, a metallic glass structure, or a small nanocrystalline structure having various crystallographic orientations, significantly improves reliability and performance of the non-volatile memory cell 106.

It has been discovered that the formation of the bottom electrode contact 204 having the titanium nitride completely free of trace halogens produced from the organometallic compound using either TDMAT or (CH₃)₅C₅Ti(CH₃)₃ can extend a 3-sigma read/write endurance limit beyond 100 K cycles and result in a 10 times improvement in the low resistance state (LRS) retention of the non-volatile memory cell 106.

It has been discovered that the bottom electrode contact 204, of the non-volatile memory cell 106, having an infusion of silicon (Si) with either the TDMAT or (CH₃)₅C₅Ti(CH₃)₃ results in a more stable read window budget (RWB) and improved endurance of the memory cells by expanding the resistance values between the presence or absence of the conductive bridge 216. The discovered read window budget is a three sigma probability tail for read current of LRS right after certain set/reset cycle minus (−) that of HRS state.

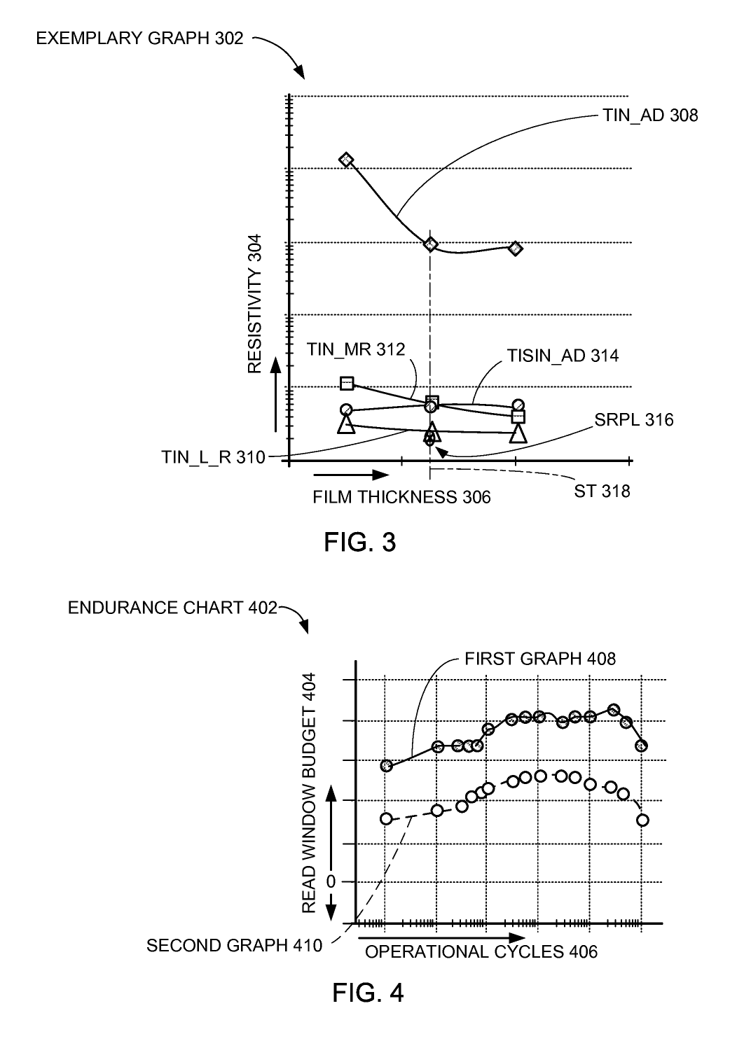

Referring now to FIG. 3, therein is shown an exemplary graph 302 of resistivity versus thickness for depositions of titanium nitride (TiN) and titanium silicon nitride (TiSN). The exemplary graph 302 depicts resistivity in increasing logarithmic units of micro-ohm cm along a Y-axis and film thickness 306 in increasing linear units of Angstroms (Å) along an X-axis.

Following are examples of four versions of the bottom electrode contact 204 of FIG. 2 using a TDMAT precursor to form a TiN_as_deposited 308, a TiN_low resistance 310, a TiN_medium_resistance 312, and a TiSiN_as_deposited 314. The TiN_as_deposited 308, the TiN_low_resistance 310, the TiN_medium_resistance 312, and the TiSiN_as_deposited 314, shown labeled and also referred to as TIN_AD, TIN_LR, TIN_MR, and TISIN_AD, respectively.

Also shown is a specific resistivity 316 of a TiN bottom electrode contact having Cl residue from a TiCl4 precursor having a specific thickness 318 identified in the exemplary graph 302 by a line formed of long and short segments. The specific resistivity 316 and the specific thickness 318 can be shown labeled and also referred to as SRPL and ST, respectively. In the exemplary graph 302 of FIG. 3, the specific resistivity 316 can be two hundred and fifteen micro-ohm cm at a thickness of two hundred and fifty Angstroms, for example.

The exemplary graph 302 shows typical differences in the resistivity 304 between a TiN bottom electrode contact having Cl residue and the bottom electrode contact 204, also known as inert electrode, of the present invention based on organometallic TDMAT precursor, free of any trace halogens, and capable of filling small contact-holes. The exemplary graph 302, for example, shows the TDMAT precursor with plasma during CVD/ALD deposition can be used to form the TiN_low_resistance 310 curve centered at the specific resistivity 316 at the specific thickness 318 of the TiN bottom electrode contact having the Cl residue.

The exemplary graph 302 also shows the TDMAT precursor with minimal or no plasma during deposition can form the TiN having the TiN_as_deposited 308 curve having resistivities per length that are more than one thousand times the specific resistivity 316 at the specific thickness 318 of the TiN bottom electrode contact with the Cl residue.

In yet another example, the exemplary graph 302, for example, shows how the TDMAT precursor with plasma during CVD/ALD deposition can be used to form the TiN shown as the TiN_medium_resistance 312 curve having resistivities per length two to three times the specific resistivity 316 at the specific thickness 318 of the TiN bottom electrode contact with the Cl residue.

In yet another example, the exemplary graph 302 also shows the TDMAT precursor with minimal or no plasma during deposition can form the TiSiN with the infusion of silicon (Si) having the TiSiN_as_deposited 314 curve having resistivities per length having resistivities per length two to three times the specific resistivity 316 at the specific thickness 318 of the TiN bottom electrode contact with the Cl residue. Some of the four versions of the bottom electrode contact 204 can optionally be formed with a first plasma treated TiN by a high energy and long duration plasma treatment of the TDMAT.

Also, a second plasma treated of the TiN can be optionally formed by a plasma treatment having less energy and duration than was used to form the first plasma treated TiN to produce some of the four versions of the bottom electrode contact 204 with less time and energy than the first plasma treated TiN without sacrificing the reliability or resilience of the non-volatile memory cell 106 of FIG. 1. Also the TiN can be treated with silicon (Si) to form the titanium silicon nitride by infusing the silicon (Si) with the TDMAT when forming the bottom electrode contact 204, resulting in the TiSiN_as_deposited 314 characteristic curve.

For purposes of discussion, this embodiment describes the bottom electrode contact 204 or inert electrode form having titanium. It is understood that with the use of other precursors, the bottom electrode contact 204 could be formed having other metals and still be free of halogen constituents. For example, the bottom electrode contact 204 could be formed having tungsten (W) free of fluorine constituents, using appropriate organometallic precursors, and a CVD/ALD deposition process.

It has been discovered that either the TDMAT or (CH₃)₅C₅Ti(CH₃)₃ precursor with minimal or no plasma during CVT/ALD deposition provides the flexibility and control to form the bottom electrode contact 204 to having any specific thickness including the specific thickness 318 of the TiN bottom electrode contact with the Cl residue by adjusting the time or duration for allocated to the deposition process for optimum performance, reliability, costs, RWB stability, or any combination thereof.

Referring now to FIG. 4, therein is shown an exemplary graph plotting read memory cyclic set and reset endurance exemplifying one of the four versions of the bottom electrode contact 204 of FIG. 3. An endurance chart 402 indicates read window budgets 404 above and below a zero read window budget reference in linear units of nano-ampere (nA) along a Y-axis and corresponding set and reset cycles 406 of operation in increasing logarithmic units of cycles along an X-axis.

The read window budget (RWB) is a three sigma probability tail for read current of LRS right after certain set/reset cycle minus (−) that of HRS state. Read voltage was 0.1V in the set direction. If RWB of three sigma is positive, the LRS and HRS states can be distinguished at the percentage of 3-sigma out of one hundred percent which equals to approximately 99.9 percent. If the RWB is negative, read current of tail LRS and HRS bits overlap, and the LRS and HRS states are difficult to interpret. Thirty five uA and forty five UA are mean compliance currents for set operations. If more current is utilized, a conductive filament at the LRS state will be stabilized and the three sigma tail for the read current of LRS increases.

For example, a first graph 408, plotted as a solid line across one hundred thousand read cycles over, does not intersect a second graph 410, shown as a dashed line below the first graph 408. The first graph 408 represents a bottom electrode contact, such as the bottom electrode contact 204, with a TDMAT precursor—based TiN deposited thickness of four hundred Å, polished by using CMP to a BEC plug height of between four hundred to seven hundred Å, and operated at one and eight tenths reset voltage and a forty eight μA set compliance current.

The second graph 410 represents the bottom electrode contact, such as the bottom electrode contact 204, with TDMAT precursor—based TiN deposited thickness of four hundred Å, polished by using CMP to a BEC plug height of between four hundred to seven hundred Å, and operated at one and eight tenths reset voltage and thirty five μA set compliance current. The first graph 408 and the second graph 410 plotted on the endurance chart 402, exhibit similarly shaped curves across one hundred thousand program—erase cycles, is indicative of controlled read window budgets at different read currents for a given voltage.

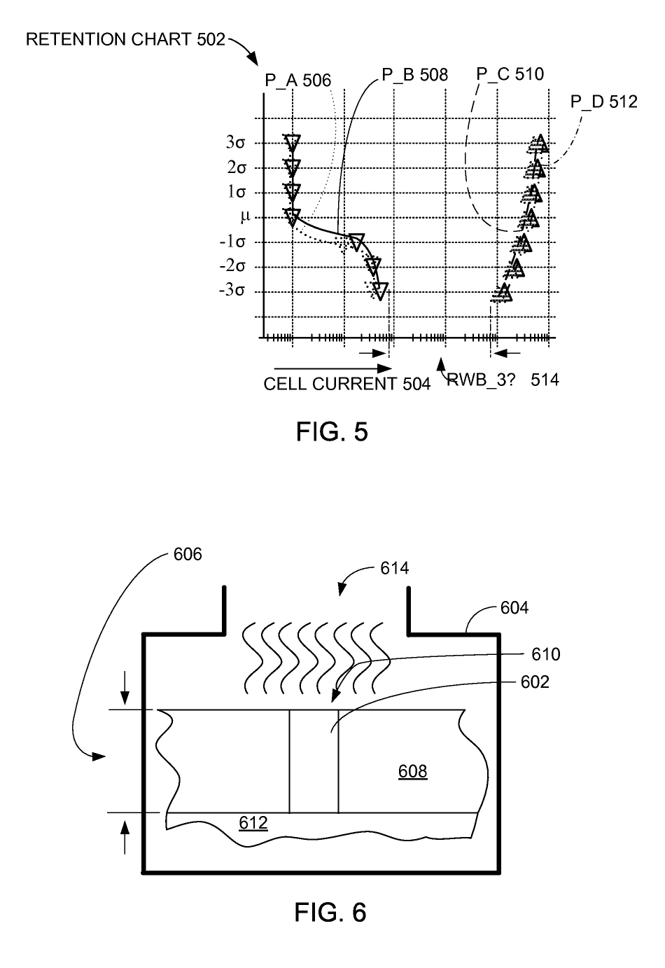

Referring now to FIG. 5, therein is shown is an exemplary graph plotting memory state retention stability of a memory cell of one of the four versions of the bottom electrode contact 204 of FIG. 3. An exemplary retention chart 502 is shown having a Y-axis identifying a 3σ (sigma) distribution with a median 0 sigma μ (mu) and an X-axis indicating read cell current 504 in increasing logarithmic units of nano-ampere (nA).

Four plots are shown and represent an example of one of the four versions of the bottom electrode contact 204, also known as the inert electrode, of the non-volatile memory cell 106 of FIG. 1. The four plots are individually labeled and identified as p_a 506, p_b 508, p_c 510, and p_d 512. The set compliance current was set to thirty five uA and the read voltage was 0.1 volt.

Plot p_a 506, indicated with dotted triangle data points connected by dotted segments, depicts HRS state after ten thousand set/reset cycles from a memory cell having a cell resistance representing a data condition state after the memory cell has been exposed to one hundred and fifty degrees Celsius for a period of one hour. Plot p_b 508, indicated with solid triangle data points connected by solid segments, depicts ten thousand HRS state after ten thousand set/reset cycles from the memory cell having a cell resistance representing a data condition state before the memory cell has been exposed to one hundred and fifty degrees Celsius for a period of one hour.

Plot p_c 510, indicated with dashed shaded triangle data points connected by dashed segments, depicts LRS state after ten thousand set/reset cycles from a memory cell having a cell resistance representing a data condition state after the memory cell has been exposed to one hundred and fifty degrees Celsius for a period of one hour. Plot p_d 512, indicated with solid shaded triangle data points connected by dashed-dot segments, depicts LRS state after ten thousand set/reset cycles from the memory cell having a cell resistance representing a data condition state before the memory cell has been exposed to one hundred and fifty degrees Celsius for a period of one hour.

It has been discovered that the non-volatile memory cell 106 having the bottom electrode contact 204 of titanium nitride (TiN) formed from the organometallic titanium compound, using either TDMAT or (CH₃)₅C₅Ti(CH₃)₃, electrochemically inert and free of trace halogens retains the programmed data condition state for over ten thousand reads with a 3-sigma range unaffected by one hundred and fifty degrees Celsius exposure for one hour to provide exceptional reliability and data retention.

It has been discovered that the non-volatile memory cell 106 having the bottom electrode contact 204 of titanium nitride (TiN) formed from the organometallic titanium compound, using either TDMAT or (CH₃)₅C₅Ti(CH₃)₃, electrochemically inert and free of trace halogens results in a first product improvement to the non-volatile memory cell 106. The first product improvement is an ability to retain the programmed data condition state of a zero or HRS state after ten thousand program/erase cycles, with a 3-sigma read cell current range between 0.1-8.0 nA that is unaffected by one hundred and fifty degrees Celsius exposure for one hour, to provide exceptional reliability and data retention.

It has been discovered that the non-volatile memory cell 106 having the bottom electrode contact 204 of titanium nitride (TiN) formed from the organometallic titanium compound, using either TDMAT or (CH₃)₅C₅Ti(CH₃)₃, electrochemically inert and free of trace halogens results in second product improvement to the non-volatile memory cell 106. The second product improvement is an ability to retain the programmed data condition state of a one or LRS state after ten thousand reads with a 3-sigma read cell current range between 800 nano-Amperes (nA) and 10 micro-Amperes (μA) unaffected by one hundred and fifty degrees Celsius exposure for one hour to provide exceptional reliability and data retention.

It has been discovered that the non-volatile memory cell 106 having the bottom electrode contact 204 of titanium nitride (TiN) formed from the organometallic titanium compound, using either TDMAT or (CH₃)₅C₅Ti(CH₃)₃, electrochemically inert and free of trace halogens maintains a minimum read cell current spread 514, shown and identified as RWB_{—}3σ, of at least six hundred and ninety two nA between the programmed data condition states of a LRS and HRS for over ten thousand reads, unaffected by one hundred and fifty degrees Celsius exposure for one hour to provide exceptional reliability and data retention.

Referring now to FIG. 6, therein is shown is a partial cross-sectional view a bottom electrode contact in a deposition processing phase of manufacturing. Shown is a bottom electrode contact 602 or inert electrode, such as the bottom electrode contact 204 of FIG. 2 of titanium nitride, formed electrochemically inert with respect to a physical switching mechanism and having no halogen or halide constituents. The thick lines depict an enclosure or chamber 604, having at least one opening for the introduction or removal of gaseous matter.

The CVD, ALD, or combination of CVD and ALD (CVD/ALD) processes can be used to build-up the titanium nitride forming the bottom electrode contact 602 to a pre-determined contact depth 606 in an insulation layer 608, to determine resistive characteristics such as resistivity ranges, read currents, physical geometry sizes, material surface texture, cation affinity, technology, or performance specifications, chosen by the user and/or manufacturer. The bottom electrode contact 602, also known as the inert electrode, can be formed, as a BEC plug, in an aperture 610 of the insulation layer 608 on a planar substrate 612. The aperture 610, such as contact-hole via having a diameter less than one hundred nanometers (nm) or narrow trench having a width less than one hundred nanometers (nm) wide in the insulation layer 608 expose the planar substrate 612 or a wiring layer on the planar substrate 612. Only CVD/ALD can only fill the aperture 610 to achieve a small BEC plug. For example, a physical vapor deposition (PVD) process would be not able to fill the aperture 610. The planar substrate 612 of the integrated circuit die 102 of FIG. 1 is shown and also referred to as the SUBSTRATE.

The bottom electrode contact 602 can be deposited on the planar substrate 612 using the CVD/ALD process. The aperture 610 can be patterned by lithography and etching. The bottom electrode contact 602, also known as the inert electrode can be deposited within the aperture 610 previously patterned, and then polished to remove the overburden or deposited excess as needed.

Material additives 614 can be introduced into the chamber during the CVD/ALD processing by introducing, precursor, a plasma, a gas, or a combination thereof, such as during cycling deposition phases or with plasma to change or modify the characteristic or make-up of the bottom electrode contact 602. Addition of silicon, for example, can be performed to form the bottom electrode contact 602 of TiSN. Exposure to plasma, for example, can be used to modify resistivity characteristics of the bottom electrode contact 602.

The bottom electrode contact 602 deposited within the aperture 610 previously patterned, can be extremely small (less than 30 nm), and may be further processed using a chemical-mechanical planarization (CMP) process. The CMP process can be used to polish the bottom electrode contact 602 to remove any overburden from the deposition of the bottom electrode contact 602.

It has been discovered that only CVD and/or ALD processing for creating the bottom electrode contact 602 can be used to fill the aperture 610 as the BEC plug having a diameter less than one hundred nanometers (nm) or narrow trench having a width less than one hundred nanometers (nm) wide in the insulation layer 608.

It has been discovered that the ALD process for creating the bottom electrode contact 602 can fill the aperture 610 more uniformly than CVD and can reduce the volume of material seen at the center of the aperture 610.

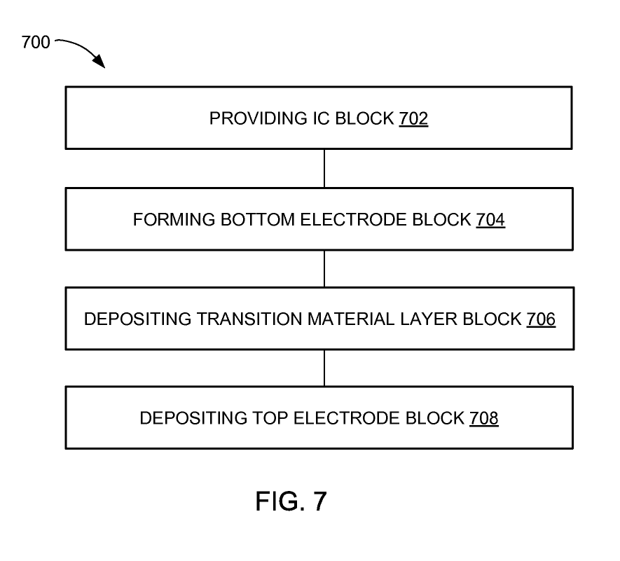

Referring now to FIG. 7, therein is shown a flow chart of a method 700 of manufacture of an integrated circuit system in a further embodiment of the present invention. The method 700 includes: providing an integrated circuit die having an address switch in a providing IC block 702; forming a bottom electrode contact, free of halogen constituents, having characteristics of a chemical vapor deposition or an atomic layer deposition process, and coupled to the address switch in a forming bottom electrode contact block 704; depositing a transition material layer directly on the bottom electrode contact in a depositing transition material layer block 706; and depositing a top electrode contact directly on the transition material layer for forming a non-volatile memory array on the integrated circuit die in a depositing top electrode block 708.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit systems/fully compatible with conventional manufacturing methods or processes and technologies.

Another important aspect of the present invention is that it valuably supports and services the historical trend of reducing costs, simplifying systems, and increasing performance for integrated circuit systems with non-volatile memory.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit system comprising:
providing an integrated circuit die having an address switch;
forming a bottom electrode contact, free of halogen constituents, having characteristics of a chemical vapor deposition or an atomic layer deposition process, and coupled to the address switch;
depositing a transition material layer directly on the bottom electrode contact; and
depositing a top electrode contact directly on the transition material layer for forming a non-volatile memory array on the integrated circuit die.

2. The method as claimed in claim 1 wherein forming the bottom electrode contact includes infusing the bottom electrode contact with silicon.

3. The method as claimed in claim 1 wherein forming the bottom electrode contact includes forming the bottom electrode contact having titanium nitride.

4. The method as claimed in claim 1 wherein forming the bottom electrode contact includes forming the bottom electrode contact with a precursor of tetrakis-dimethylamino titanium or trischlorodiethylamino titanium.

5. The method as claimed in claim 1 wherein forming the bottom electrode contact includes forming the bottom electrode contact containing a tungsten free of fluorine.

6. The method as claimed in claim 1 wherein forming the bottom electrode contact includes forming the bottom electrode contact with an organometallic compound as a precursor with the chemical vapor deposition or the atomic layer deposition process.

7. A method of manufacture of an integrated circuit system comprising:
providing an integrated circuit die having an address switch;
forming a bottom electrode contact, free of halogen constituents, having characteristics of a chemical vapor deposition or an atomic layer deposition process, and coupled to the address switch;
depositing a transition material layer directly on the bottom electrode contact; and
depositing a top electrode contact, over the integrated circuit die, directly on the transition material layer, for forming a non-volatile memory array on the integrated circuit die.

8. The method as claimed in claim 7 wherein forming the bottom electrode contact includes forming the bottom electrode contact having a resistivity between one hundred micro-ohm cm to 1 ohm cm.

9. The method as claimed in claim 7 further comprising:
providing a planar substrate of the integrated circuit die; and
wherein:
forming the bottom electrode contact includes forming the bottom electrode contact on the planar substrate.

10. The method as claimed in claim 7 further comprising:
forming a narrow trench, of the integrated circuit die, having a width less than one hundred nanometers; and
wherein:
forming the bottom electrode contact includes forming the bottom electrode contact in the narrow trench.

11. The method as claimed in claim 7 wherein forming the bottom electrode contact includes forming the bottom electrode contact having an amorphous structure or a metallic glass structure.

12. The method as claimed in claim 7 further comprising:
forming a contact-hole via, of the integrated circuit die, having a diameter less than one hundred nanometers; and
wherein:
forming the bottom electrode contact includes forming the bottom electrode contact in the contact-hole via.

13. An integrated circuit system comprising:
an integrated circuit die having an address switch;
a bottom electrode contact, free of halogen constituents, characteristic of a chemical vapor deposition or an atomic layer deposition, and coupled to the address switch;
a transition material layer directly on the bottom electrode contact; and
a top electrode contact, directly on the transition material layer, for forming a non-volatile memory array on the integrated circuit die.

14. The system as claimed in claim 13 further comprising a titanium silicon nitride, having the characteristic of the chemical vapor deposition or the atomic layer deposition, in the bottom electrode contact.

15. The system as claimed in claim 13 further comprising a tungsten free of the halogen constituents, having the characteristic of the chemical vapor deposition or the atomic layer deposition, in the bottom electrode contact.

16. The system as claimed in claim 13 wherein the bottom electrode contact has a pre-determined contact depth for determining resistivity of the bottom electrode contact.

17. The system as claimed in claim 13 wherein the bottom electrode contact has a resistivity between one hundred micro-ohm cm to 1 ohm cm.

18. The system as claimed in claim 13 wherein the top electrode contact is over the integrated circuit die.

19. The system as claimed in claim 18 further comprising:
a planar substrate of the integrated circuit die; and
wherein:
the bottom electrode contact is on the planar substrate.

20. The system as claimed in claim 18 further comprising:
a narrow trench, of the integrated circuit die, having a width less than one hundred nanometers; and
wherein:
the bottom electrode contact is in the narrow trench.

21. The system as claimed in claim 18 wherein the bottom electrode contact has an amorphous structure or a metallic glass structure.

22. The system as claimed in claim 18 further comprising:
a contact-hole via, of the integrated circuit die, having a diameter less than one hundred nanometers; and
wherein:
the bottom electrode contact is in the contact-hole via.
